(19) United States
(12) Patent Application Publication
(10) Pub. No.: US 2014/0361307 A1
(43) Pub. Date: Dec. 11, 2014

(54) LIGHT EMITTING CHIP

(71) Applicant: DISCO CORPORATION, Tokyo (JP)

(72) Inventors: Takashi Okamura, Tokyo (JP); Minoru Suzuki, Tokyo (JP)

(73) Assignee: DISCO CORPORATION, Tokyo (JP)

(21) Appl. No.: 14/295,806

(22) Filed: Jun. 4, 2014

(30) Foreign Application Priority Data
Jun. 6, 2013 (JP) 2013-119652

(51) Int. Cl. H01L 33/60; H01L 33/62; H01L 33/32

(52) U.S. Cl. CPC H01L 33/60; H01L 33/32; H01L 33/62
USPC 257/76

(57) ABSTRACT

A light emitting chip including a device chip having a transparent substrate and a light emitting layer formed on a front side of the transparent substrate, and a transparent resin layer provided on a back side of the transparent substrate. The transparent resin layer contains transparent particles for transmitting and scattering light emitted from the light emitting layer.

### BACKGROUND OF THE INVENTION

1. Field of the Invention

The present invention relates to a light emitting chip including a device chip having a light emitting layer.

2. Description of the Related Art

A light emitting device such as LED (Light Emitting Diode) and LD (Laser Diode) is in practical use. Usually, such a light emitting device includes a light emitting chip having a device chip formed with a light emitting layer capable of emitting light by an application of a voltage. The device chip is manufactured in the following manner. First, an epitaxial layer (crystal layer) as a light emitting layer is grown in each of regions partitioned by a plurality of crossing division lines formed on a crystal growing substrate. Thereafter, the crystal growing substrate is divided along the division lines to obtain a plurality of individual device chips for individual light emitting chips.

In the case that the light emitting layer in the device chip is an InGaN light emitting layer capable of emitting green or blue light, a sapphire substrate is generally used as the crystal growing substrate. In this case, the device chip is formed by epitaxially growing an n-type GaN semiconductor layer, an InGaN light emitting layer, and a p-type GaN semiconductor layer in this order on the sapphire substrate. The n-type GaN semiconductor layer and the p-type GaN semiconductor layer are respectively formed with external electrodes.

A back side of the device chip (the sapphire substrate side) is fixed to a lead frame as a base, and a front side of the device chip (the light emitting layer side) is covered with a lens member, thereby forming a light emitting diode. In such a light emitting diode, an improvement in luminance is considered as an important issue, and there have hitherto been proposed various methods for improving a light extraction efficiency (see Japanese Patent Laid-Open No. Hei 4-10670, for example).

### SUMMARY OF THE INVENTION

The light generated in the light emitting layer by the application of a voltage is emitted mainly from two principal surfaces (a front side and a back side) of a stacked layer including the light emitting layer. For example, the light emitted from the front side of the stacked layer (the principal surface on the lens member side) is transmitted through the lens member to the outside of the light emitting diode. On the other hand, the light emitted from the back side of the stacked layer (the principal surface on the sapphire substrate side) propagates in the sapphire substrate, and a part of this light is reflected on an interface between the sapphire substrate and the lead frame and then returned to the stacked layer.

In the case of using a thin sapphire substrate in the device chip for the purpose of improving the processability in cutting or the like, a distance between the back side of the stacked layer and the interface between the sapphire substrate and the lead frame is short. In this case, a proportion of light reflected on the interface between the sapphire substrate and the lead frame and returned to the stacked layer is higher than that in the case of using a thick sapphire substrate. The light returned to the stacked layer is absorbed by the stacked layer. Accordingly, when the proportion of light returned to the stacked layer is high, the light extraction efficiency is reduced.

It is therefore an object of the present invention to provide a light emitting chip which can improve the light extraction efficiency.

In accordance with an aspect of the present invention, there is provided a light emitting chip including a device chip having a transparent substrate and a light emitting layer formed on a front side of the transparent substrate; a transparent resin layer provided on a back side of the transparent substrate; and transparent particles contained in the transparent resin layer for transmitting and scattering light emitted from the light emitting layer.

With this configuration, the light emitted from the light emitting layer is scattered by the transparent particles contained in the transparent resin layer. Accordingly, it is possible to reduce a proportion of light emerging from the back side of the device chip (i.e., the back side of the transparent substrate) in a direction perpendicular thereto, next reflected on a lead frame or the like bonded through the transparent resin layer to the device chip, and next returned to the light emitting layer. Further, since the transparent particles are contained in the transparent resin layer, the thickness of the transparent resin layer can be increased over the case that the transparent particles are not contained in the transparent resin layer with the same bonding force maintained. Accordingly, it is possible to increase a proportion of light emitted from a side surface of the transparent resin layer.

Preferably, the transparent substrate includes a sapphire substrate, and the light emitting layer includes a GaN semiconductor layer. With this configuration, the light emitting chip of the present invention is provided as a light emitting chip capable of emitting blue or green light, wherein the light extraction efficiency can be improved. Further, even when the thickness of the sapphire substrate is reduced, the reflected light from a lead frame or the like can be emitted from a position different from the light emitting layer. Accordingly, a thin sapphire substrate can be used without reducing the light extraction efficiency, and good processability of the sapphire substrate as a crystal growing substrate can be ensured.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a schematic perspective view showing a configuration of a light emitting diode according to a first preferred embodiment of the present invention;

FIG. 2 is a schematic sectional view showing a manner of emission of light from a light emitting chip included in the light emitting diode shown in FIG. 1;

FIG. 3 is a schematic sectional view showing a manner of emission of light from a light emitting chip included in a light emitting diode according to a first comparison to be compared with the first preferred embodiment shown in FIG. 2;

FIG. 4A is a schematic perspective view showing a configuration of a light emitting diode according to a second preferred embodiment of the present invention;

FIG. 4B is a schematic sectional view of the light emitting diode shown in FIG. 4A;

FIG. 5 is a schematic perspective view showing a configuration of a light emitting diode according to a third preferred embodiment of the present invention;

FIG. 6 is a schematic sectional view showing a manner of emission of light from a light emitting chip included in the light emitting diode shown in FIG. 5;

FIG. 7 is a schematic sectional view showing a manner of emission of light from a light emitting chip included in a light emitting diode according to a second comparison to be compared with the third preferred embodiment shown in FIG. 6;

FIG. 8A is a schematic perspective view showing a configuration of a light emitting diode according to a fourth preferred embodiment of the present invention;

FIG. 8B is a schematic sectional view of the light emitting diode shown in FIG. 8A;

FIG. 9 is a graph showing results of measurement of luminance in Examples 1 to 3 and Comparison;

FIG. 10 is a graph showing results of measurement of luminance in Examples 4 to 6; and

FIG. 11 is a graph showing results of measurement of luminance in Examples 7 to 12 and Comparison.

### DETAILED DESCRIPTION OF THE PREFERRED EMBODIMENTS

### First Preferred Embodiment

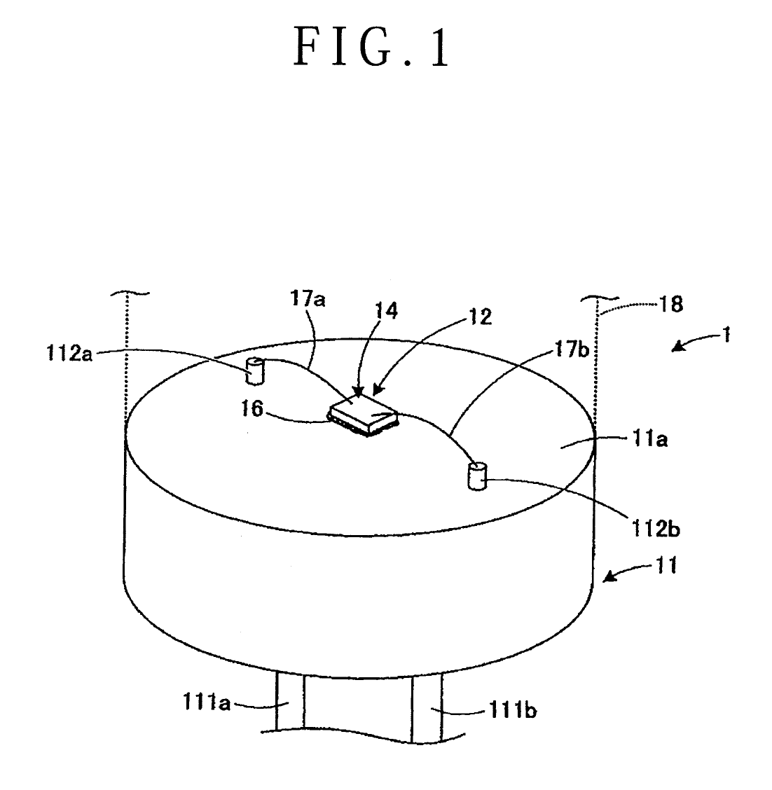

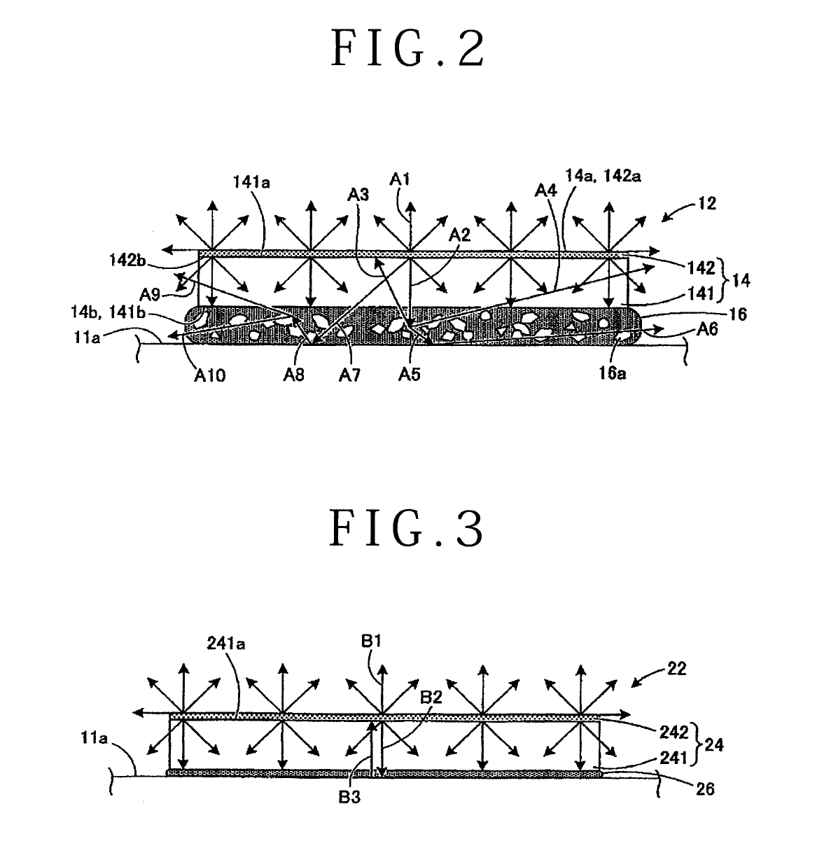

A preferred embodiment of the present invention will now be described with reference to the attached drawings. FIG. 1 is a schematic perspective view showing a configuration of a light emitting diode 1 according to a first preferred embodiment of the present invention, and FIG. 2 is a schematic sectional view showing a manner of emission of light from a light emitting chip 12 included in the light emitting diode 1 shown in FIG. 1. As shown in FIG. 1, the light emitting diode 1 includes a lead frame 11 as a base and the light emitting chip 12 fixedly supported to the lead frame 11.

The lead frame 11 is formed of metal, for example, and it has a solid cylindrical shape. Two conductive lead members 111a and 111b are provided on a back side of the lead frame 11 corresponding to one principal surface. The lead members 111a and 111b are insulated from each other and function as a positive electrode and a negative electrode of the light emitting diode 1, respectively. The lead members 111a and 111b are connected through wires (not shown) or the like to an external power source (not shown).

Two connection terminals 112a and 112b insulated from each other are provided on a front side 11a of the lead frame 11 corresponding to the other principal surface so as to be spaced a predetermined distance from each other. The connection terminal 112a and the lead member 111a are connected with each other in the lead frame 11. The connection terminal 112b and the lead member 111b are connected with each other in the lead frame 11. Accordingly, potentials of the connection terminals 112a and 112b are almost the same as potentials of the lead frames 111a and 111b, respectively.

The light emitting chip 12 is provided on the front side 11a of the lead frame 11 at a position between the connection terminals 112a and 112b. As shown in FIG. 2, the light emitting chip 12 has a device chip 14 and a transparent resin layer 16 provided on a back side 14b of the device chip 14. The device chip 14 includes a sapphire substrate 141 having a rectangular shape as viewed in plan and a stacked layer 142 provided on a front side 141a of the sapphire substrate 141. The stacked layer 142 includes a plurality of semiconductor layers (GaN semiconductor layers) formed by using GaN based semiconductor materials.

The stacked layer 142 is formed by the epitaxial growth of an n-type semiconductor layer (e.g., n-type GaN layer) in which electrons function as majority carrier, a semiconductor layer (e.g., InGaN layer) as a light emitting layer, and a p-type semiconductor layer (e.g., p-type GaN layer) in which holes function as majority carrier. These layers are epitaxially grown in this order. The sapphire substrate 141 is formed with two electrodes (not shown) respectively connected to the n-type semiconductor layer and the p-type semiconductor layer for applying a voltage to the stacked layer 142. As a modification, these electrodes may be included in the stacked layer 142.

The transparent resin layer 16 is formed of a resin material such as a die bonding agent capable of transmitting light emitted from the light emitting layer. The transparent resin layer 16 is provided on the whole of the back side 14b of the device chip 14 to bond the back side 14b of the device chip 14 and the front side 11a of the lead frame 11. The transparent resin layer 16 contains transparent particles 16a capable of transmitting and scattering light emitted from the light emitting layer. The transparent particles 16a are formed of glass bead, glass frit, or Al₂O₃, for example. The transparent particles 16a are mixed in the transparent resin layer 16 with a predetermined content allowing stable exhibition of the bonding force of the transparent resin layer 16.

As shown in FIG. 1, the two connection terminals 112a and 112b provided on the lead frame 11 are respectively connected through conductive lead wires 17a and 17b to the two electrodes of the light emitting chip 12. Accordingly, a voltage from the power source connected to the lead members 111a and 111b is applied to the stacked layer 142. When the voltage is applied to the stacked layer 142, electrons move from the n-type semiconductor layer into the semiconductor layer as the light emitting layer, and holes move from the p-type semiconductor layer into the semiconductor layer. As a result, recombination of electrons and holes occur in the semiconductor layer as the light emitting layer, thereby emitting light having a predetermined wavelength. In this preferred embodiment, the semiconductor layer as the light emitting layer is formed of a GaN based semiconductor material, so that blue or green light corresponding to the bandgap of the GaN based semiconductor material.

A dome-shaped lens member 18 is mounted on an outer circumference of the front side 11a of the lead frame 11 so as to cover the front side 14a of the device chip 14. The lens member 18 is formed of a material such as resin having a predetermined refractive index, thereby refracting light emitted from the stacked layer 142 of the device chip 14 to guide the light to an outside of the light emitting diode 1 in a predetermined direction. In this manner, the light emitted from the device chip 14 is extracted through the lens member 18 to the outside of the light emitting diode 1.

There will now be described a luminance improving effect by the light emitting diode 1 according to the first preferred embodiment in comparison with a light emitting diode according to a first comparison shown in FIG. 3. FIG. 3 is a schematic sectional view showing a manner of emission of light from a light emitting chip 22 included in the light emitting diode according to the first comparison to be compared with the first preferred embodiment. As shown in FIG. 3, the light emitting diode according to the first comparison is similar in configuration to the light emitting diode 1 according to the first preferred embodiment except that the transparent resin layer 16 is replaced by a transparent resin layer 26. More specifically, the transparent resin layer 26 in the light emitting chip 22 according to the first comparison shown in FIG. 3 does not contain transparent particles, so that a thickness of the transparent resin layer 26 is smaller than a thickness of the transparent resin layer 16 in the first preferred embodiment. As similar to the first preferred embodiment, the light emitting chip 22 includes a device chip 24 having a sapphire substrate 241 rectangular in plan and a stacked layer 242 formed on a front side 241a of the sapphire substrate 241. The device chip 24 is bonded through the transparent resin layer 26 to the front side 11a of the lead frame 11.

In the light emitting diode 1 (see FIG. 1) according to the first preferred embodiment, light generated in the semiconductor layer as the light emitting layer is emitted mainly from a front side 142a of the stacked layer 142 (i.e., the front side 14a of the light emitting chip 14) and a back side 142b of the stacked layer 142 as shown in FIG. 2. The light emitted from the front side 142a of the stacked layer 142 (e.g., optical path A1) is extracted through the lens member 18 (see FIG. 1) to the outside of the light emitting diode 1 as described above. On the other hand, the light emitted from the back side 142b of the stacked layer 142 and propagating downward at right angles thereto (optical path A2) is transmitted through the sapphire substrate 141 to enter the transparent resin layer 16, and this light is transmitted through the transparent resin layer 16. During the transmission of the light through the transparent resin layer 16, the light is scattered by the transparent particles 16a. Examples of the light scattered by the transparent particles 16a are shown as light propagating along optical paths A3, A4, and A5.

The light propagating along the optical path A3 is transmitted through the sapphire substrate 141 to enter the stacked layer 142, in which the light is absorbed and it cannot be extracted to the outside of the light emitting diode 1. The light propagating along the optical path A4 is transmitted through the sapphire substrate 141 and then emitted from a side surface of the sapphire substrate 141 to the outside of the light emitting diode 1. The light propagating along the optical path A5 is transmitted through the transparent resin layer 16 and then reflected on the front side 11a of the lead frame 11 (optical path A6). The light propagating along the optical path A6 is emitted from a surface of the transparent resin layer 16 to the outside of the light emitting diode 1.

For example, the light emitted from the back side 142b of the stacked layer 142 and propagating along an optical path A7 is transmitted through the sapphire substrate 141 and the transparent resin layer 16 and then reflected on the front side 11a of the lead frame 11 (optical path A8). The light propagating along the optical path A8 is transmitted through the transparent resin layer 16 and then scattered by the transparent particles 16a. A part of the light scattered by the transparent particles 16a is emitted from the side surface of the sapphire substrate 141 to the outside of the light emitting diode 1 (optical path A9), and another part of the light scattered by the transparent particles 16a is emitted from the side surface of the transparent resin layer 16 to the outside of the light emitting diode 1 (optical path A10).

In contrast thereto, optical paths B1 and B2 in the light emitting chip 22 according to the first comparison shown in FIG. 3 are similar to the optical paths A1 and A2 in the light emitting chip 12 according to the first preferred embodiment shown in FIG. 2, respectively. However, the scattering of light by the transparent particles 16a in the first preferred embodiment does not occur in the first comparison. Accordingly, almost all of the light propagating along the optical path B2 is transmitted through the transparent resin layer 26 and comes into incidence upon the front side 11a of the lead frame 11 in a direction perpendicular thereto. Then, this light is reflected on the front side 11a of the lead frame 11 in the direction perpendicular thereto (optical path B3). The light propagating along the optical path B3 perpendicular to the front side 11a of the lead frame 11 is transmitted through the transparent resin layer 26 and the sapphire substrate 241 to enter the stacked layer 242, in which the light is absorbed and it cannot be extracted to the outside of the light emitting diode. Thus, in the first comparison, almost all of the light emitted from the stacked layer 242 and propagating along the optical path B2 is returned to the stacked layer 242 along the optical path B3 and absorbed by the stacked layer 242, so that it cannot be extracted to the outside of the light emitting diode.

In the light emitting diode 1 according to the first preferred embodiment, the light emitted from the stacked layer 142 and propagating along the optical path A2 is scatted by the transparent particles 16a, and a part of the scattered light can be extracted along the optical paths A4 and A6, for example, to the outside of the light emitting diode 1. Accordingly, as compared with the light propagating along the optical path B2 in the first comparison, the proportion of the light returned to the stacked layer 142 to the light propagating along the optical path A2 can be reduced. That is, the proportion of the light emitted from the sapphire substrate 141 can be increased to thereby improve the light extraction efficiency. As a result, the luminance of the light emitting diode 1 can be improved. Further, since the transparent resin layer 16 contains the transparent particles 16a, the thickness of the transparent resin layer 16 can be increased as keeping a bonding force similar to that of the transparent resin layer 26 in the first comparison. Accordingly, it is possible to increase the proportion of the light emitted from the side surface of the transparent resin layer 16 after the light is scattered by the transparent particles 16a or transmitted through the sapphire substrate 141.

There will now be described a second preferred embodiment and a third preferred embodiment of the present invention different from the first preferred embodiment. In the following description of the second preferred embodiment and the third preferred embodiment, the same parts as those in the first preferred embodiment are denoted by the same reference symbols and the description thereof are omitted.

### Second Preferred Embodiment

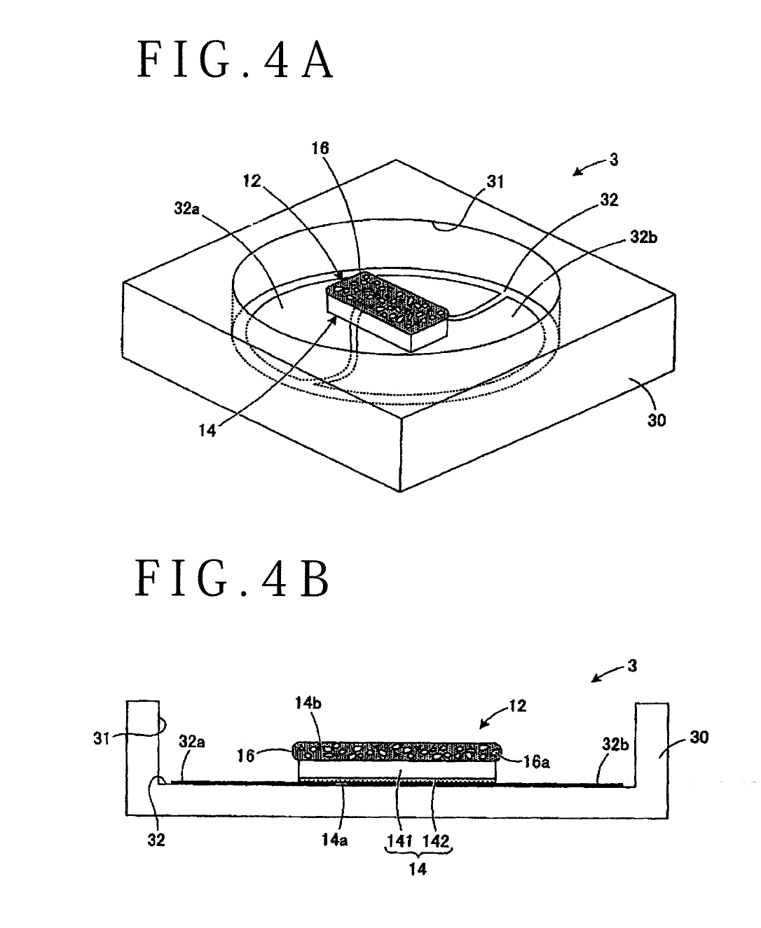

FIG. 4A is a schematic perspective view showing a configuration of a light emitting diode 3 according to the second preferred embodiment, and FIG. 4B is a schematic sectional view of the light emitting diode 3 shown in FIG. 4A. As shown in FIGS. 4A and 4B, the light emitting diode 3 according to the second preferred embodiment includes a package 30 having a recess 31 and a light emitting chip 12 fixedly supported to a bottom surface of the recess 31 as a mounting surface 32. Two connection electrodes 32a and 32b insulated from each other are provided on the mounting surface 32 so as to be spaced a predetermined distance from each other.

The light emitting chip 12 according to the second preferred embodiment is similar to the light emitting chip 12 according to the first preferred embodiment. That is, the light emitting chip 12 according to the second preferred embodiment includes a device chip 14 and a transparent resin layer 16 provided on a back side 14b of the device chip 14, wherein the transparent resin layer 16 contains transparent particles 16a. Unlike the first preferred embodiment, the light emitting chip 12 is turned upside down and a front side 14a of the device chip 14 is fixed to the mounting surface 32 of the package 30. Two electrodes (not shown) are provided on the front side 14a of the device chip 14. These two electrodes are formed as projecting terminals called bumps. By fixing the front side 14a of the device chip 14 to the mounting surface 32, these bumps are respectively connected to the connection electrodes 32a and 32b. Thus, the light emitting chip 12 is flip-chip mounted.

### Third Preferred Embodiment

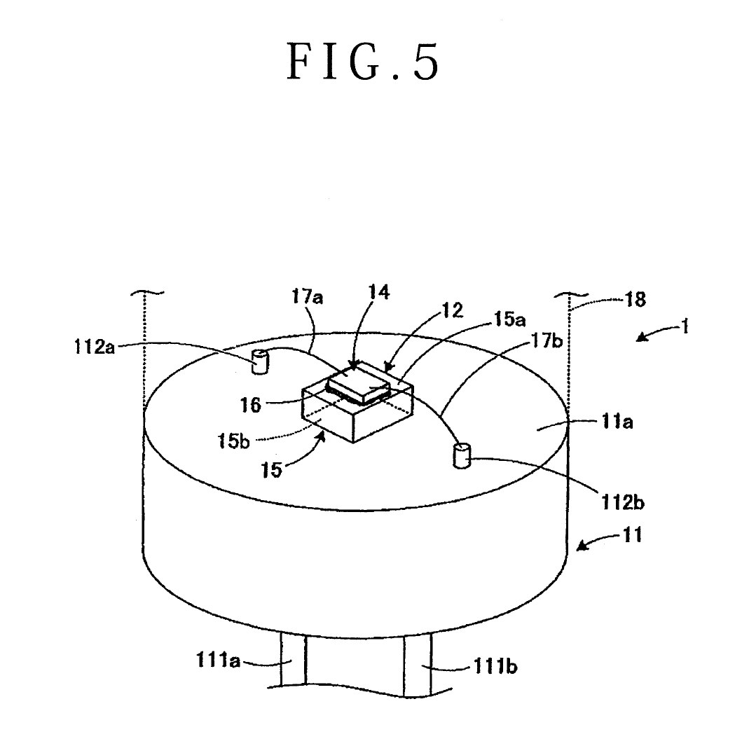

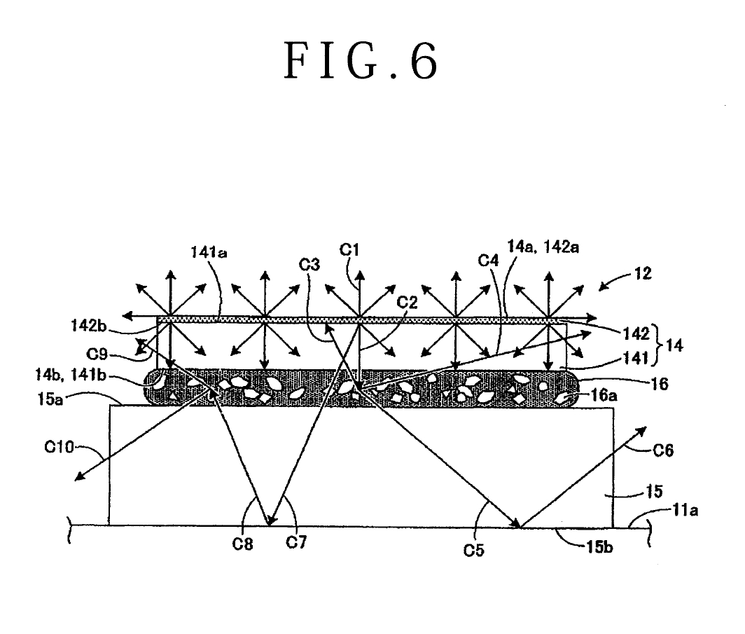

FIG. 5 is a schematic perspective view showing a configuration of a light emitting diode 1 according to the third preferred embodiment, and FIG. 6 is a schematic sectional view showing a manner of emission of light from a light emitting chip 12 included in the light emitting diode 1 shown in FIG. 5. The light emitting diode 1 according to the third preferred embodiment further includes a transparent member 15 in addition to the configuration of the light emitting diode 1 according to the first preferred embodiment, wherein the transparent member 15 is interposed between the transparent resin layer 16 and the front side 11a of the lead frame 11.

The transparent member 15 is bonded through the transparent resin layer 16 to the back side 14b of the device chip 14. The transparent member 15 is formed of a material capable of transmitting light emitted from the light emitting layer, such as glass (e.g., soda-lime glass and borosilicate glass) and resin. An area of the front side 15a of the transparent member 15 is larger than an area of the back side 141b of the sapphire substrate 141. The transparent member 15 preferably has a thickness greater than or equal to the thickness of the sapphire substrate 141. The back side 15b of the transparent member 15 is bonded through resin (not shown) to the front side 11a of the lead frame 11, wherein this resin is similar in material to the transparent resin layer 16 except the transparent particles 16a.

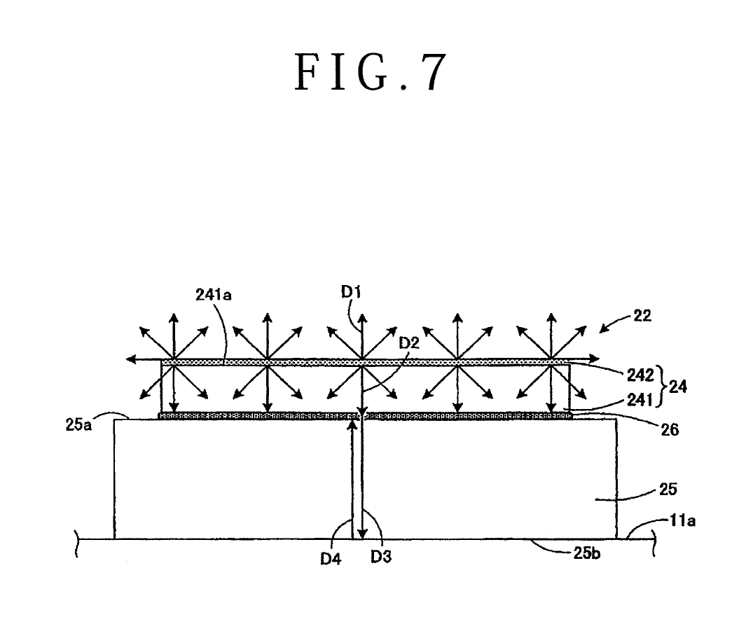

There will now be described a luminance improving effect by the light emitting diode 1 according to the third preferred embodiment in comparison with a light emitting diode according to a second comparison shown in FIG. 7. FIG. 7 is a schematic sectional view showing a manner of emission of light from a light emitting chip 22 included in the light emitting diode according to the second comparison to be compared with the third preferred embodiment. As shown in FIG. 7, the light emitting diode according to the second comparison is similar in configuration to the light emitting diode 1 according to the third preferred embodiment except that the transparent resin layer 16 is replaced by a transparent resin layer 26. More specifically, the transparent resin layer 26 in the light emitting chip 22 according to the second comparison shown in FIG. 7 does not contain transparent particles, so that a thickness of the transparent resin layer 26 is smaller than the thickness of the transparent resin layer 16 in the third preferred embodiment. As similar to the third preferred embodiment, the light emitting chip 22 includes a device chip 24 having a sapphire substrate 241 rectangular in plan and a stacked layer 242 formed on a front side 241a of the sapphire substrate 241. The device chip 24 is bonded through the transparent resin layer 26 to a transparent member 25.

In the third preferred embodiment shown in FIG. 6, light generated in the semiconductor layer as the light emitting layer is emitted mainly from the front side 142a of the stacked layer 142 (i.e., the front side 14a of the light emitting chip 14) and the back side 142b of the stacked layer 142. The light emitted from the front side 142a of the stacked layer 142 (e.g., optical path C1) is extracted through the lens member 18 (see FIG. 5) to the outside of the light emitting diode 1 as described above. On the other hand, the light emitted from the back side 142b of the stacked layer 142 and propagating downward at right angles thereto (optical path C2) is transmitted through the sapphire substrate 141 to enter the transparent resin layer 16, and this light is transmitted through the transparent resin layer 16. During the transmission of the light through the transparent resin layer 16, the light is scattered by the transparent particles 16a. Examples of the light scattered by the transparent particles 16a are shown as light propagating along optical paths C3, C4, and C5.

The light propagating along the optical path C3 is transmitted through the sapphire substrate 141 to enter the stacked layer 142, in which the light is absorbed and it cannot be extracted to the outside of the light emitting diode 1. The light propagating along the optical path C4 is transmitted through the sapphire substrate 141 and then emitted from the side surface of the sapphire substrate 141 to the outside of the light emitting diode 1. The light propagating along the optical path C5 is transmitted through the transparent resin layer 16 and the transparent member 15 and comes into incidence upon the back side 15b of the transparent member 15. Then, this light reflected on the front side 11a of the lead frame 11 (optical path C6). The light propagating along the optical path C6 is emitted from a side surface of the transparent member 15 to the outside of the light emitting diode 1.

For example, the light emitted from the back side 142b of the stacked layer 142 and propagating along an optical path C7 is transmitted through the sapphire substrate 141, the transparent resin layer 16, and the transparent member 15 and then reflected on the front side 11a of the lead frame 11 (optical path C8). The light propagating along the optical path C8 is transmitted through the transparent member 15 to enter the transparent resin layer 16, in which the light is scattered by the transparent particles 16a. A part of the light scattered by the transparent particles 16a is emitted from the side surface of the sapphire substrate 141 to the outside of the light emitting diode 1 (optical path C9), and another part of the light scattered by the transparent particles 16a is emitted from the side surface of the transparent member 15 to the outside of the light emitting diode 1 (optical path C10).

In contrast thereto, optical paths D1 and D2 in the light emitting chip 22 according to the second comparison shown in FIG. 7 are similar to the optical paths C1 and C2 in the light emitting chip 12 according to the third preferred embodiment shown in FIG. 6, respectively. However, the scattering of light by the transparent particles 16a in the third preferred embodiment does not occur in the second comparison. Accordingly, almost all of the light propagating along the optical path D2 is transmitted through the transparent resin layer 26 to enter the transparent member 25. This light is transmitted through the transparent member 25 (optical path D3). The light propagating along the optical path D3 comes into incidence upon the front side 11a of the lead frame 11 in a direction perpendicular thereto. Then, this light is reflected on the front side 11a of the lead frame 11 in the direction perpendicular thereto (optical path D4). The optical paths D3 and D4 are perpendicular to a back side 25b of the transparent member 25. The light propagating along the optical path D4 is transmitted through a front side 25a of the transparent member 25, the transparent resin layer 26, and the sapphire substrate 241 to enter the stacked layer 242, in which the light is absorbed and it cannot be extracted to the outside of the light emitting diode. Thus, in the second comparison, almost all of the light emitted from the stacked layer 242 and propagating along the optical path D2 is returned to the stacked layer 242 along the optical paths D3 and D4 and absorbed by the stacked layer 242, so that it cannot be extracted to the outside of the light emitting diode.

As described above, the light emitting diode 1 according to the third preferred embodiment has the configuration obtained by adding the transparent member 15 to the configuration of the first preferred embodiment. Accordingly, the light scattered by the transparent particles 16a can be emitted also from the transparent member 15, so that the light extraction efficiency can be further improved.

### Fourth Preferred Embodiment

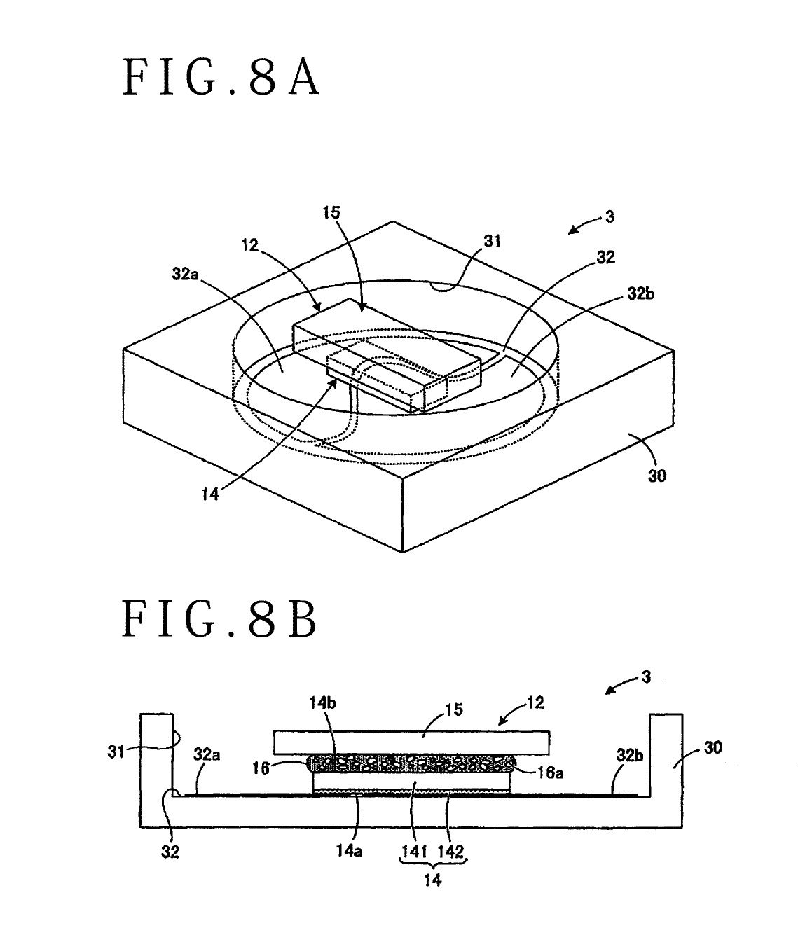

A fourth preferred embodiment of the present invention will now be described with reference to FIGS. 8A and 8B. In the following description of the fourth preferred embodiment, the same parts as those in the second preferred embodiment are denoted by the same reference symbols and the description thereof are omitted. FIG. 8A is a schematic perspective view showing a configuration of a light emitting diode 3 according to the fourth preferred embodiment, and FIG. 8B is a schematic sectional view of the light emitting diode 3 shown in FIG. 8A. As shown in FIGS. 8A and 8B, the light emitting diode 3 according to the fourth preferred embodiment further includes a transparent member 15 in addition to the configuration of the light emitting diode 3 according to the second preferred embodiment, wherein the transparent member 15 is bonded to the transparent resin layer 16. As similar to the light emitting chip 12 according to the third preferred embodiment, the light emitting chip 12 according to the fourth preferred embodiment includes the device chip 14 and the transparent member 15 bonded to each other by the transparent resin layer 16 containing the transparent particles 16a. The light emitting chip 12 according to the fourth preferred embodiment is fixed to a package 30 in such a manner that the light emitting chip 12 according to the third preferred embodiment is turned upside down and the front side 14a of the device chip 14 is bonded to the mounting surface 32 of the package 30.

In general, a sapphire substrate is hard and it is therefore not easy to process. Accordingly, it is preferable to use a thin sapphire substrate for the purpose of easy processing. In the light emitting diodes 1 and 3 according to all of the above preferred embodiments, the light extraction efficiency can be ensured by the transparent member 15 or the transparent resin layer 16 in spite of the use of the thin sapphire substrate 141. In other words, it is unnecessary to increase the thickness of the sapphire substrate 141 for the purpose of ensuring the light extraction efficiency. Accordingly, the processability of the sapphire substrate 141 is not sacrificed.

An experiment was conducted to confirm the luminance improving effect by the light emitting diodes according to the above preferred embodiments. In this experiment, a plurality of light emitting diodes similar in configuration to the light emitting diode according to the first preferred embodiment shown in FIG. 2 were prepared and the transparent particles 16a contained in the transparent resin layer 16 were varied. These light emitting diodes were used as Examples 1 to 12. Further, a light emitting diode similar in configuration to the light emitting diode according to the first comparison shown in FIG. 3 was prepared as Comparison. In this Comparison, no transparent particles were added to the transparent resin layer 26.

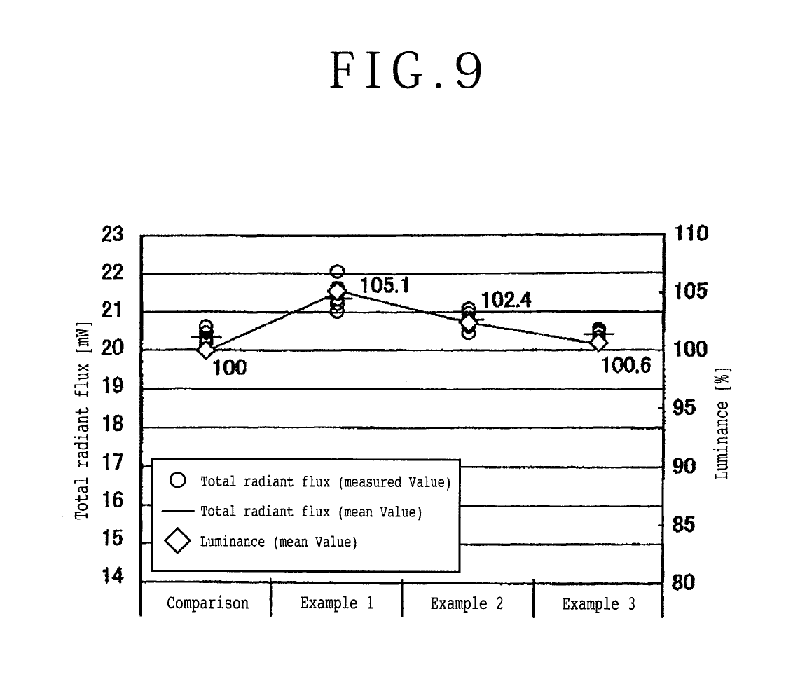

In this experiment, the luminance of the light emitting diodes as Examples 1 to 12 and Comparison was measured. More specifically, a total intensity (power) of all light emitted from each light emitting diode was measured (measurement of total radiant flux) and then converted into a luminance based on a reference value (100%) as Comparison. FIGS. 9 to 11 are graphs showing the results of this measurement. In FIGS. 9 to 11, the vertical axis represents a total radiant flux (mW) of each light emitting diode, or the luminance (%).

In all of Examples 1 to 12 and Comparison, the light emitting chips 12 and 22 (see FIGS. 2 and 3) having the same specification were used. More specifically, the light emitting chips 12 and 22 were prepared by forming the stacked layers 142 and 242 each including a GaN semiconductor layer as a light emitting layer on the sapphire substrates 141 and 241, respectively. Each of the sapphire substrates 141 and 241 has an area (length×width) of 0.595 mm×0.270 mm on the front side and the back side and a thickness (height) of 0.10 mm. Further, in all of Examples 1 to 12 and Comparison, a die bonding agent capable of transmitting light was used as the material of the transparent resin layers 16 and 26. More specifically, a silicone bond for high-luminance LED KER-3000-M2 (manufactured by Shin-Etsu Chemical Co., Ltd.) was used as the die bonding agent.

As the transparent particles 16a in Examples 1 to 3, WA (Al₂O₃) was used. In Example 1, the transparent particles 16a were those having a particle size of #600 and a representative value of 20 μm for the particle size. Further, the thickness of the transparent resin layer 16 was set to have an average of 12.1 μm and a standard deviation of 3.6. In Example 2, the transparent particles 16a were those having a particle size of #1000 and a representative value of 12 μm for the particle size. Further, the thickness of the transparent resin layer 16 was set to have an average of 7.2 μm and a standard deviation of 1.5. In Example 3, the transparent particles 16a were those having a particle size of #2000 and a representative value of 4 μm for the particle size. Further, the thickness of the transparent resin layer 16 was set to have an average of 2.7 μm and a standard deviation of 2.1.

As shown in FIG. 9, the luminance in Examples 1 to 3 is improved over that (100%) in Comparison by 0.6 to 5.1%, so that the light extraction efficiency can be improved. Further, it was confirmed from the above-mentioned conditions of Examples 1 to 3 and the results shown in FIG. 9 that the larger the particle size of the transparent particles 16a, the larger the thickness of the transparent resin layer 16 and the higher the luminance of the light emitting diode.

As the transparent particles 16a in Examples 4 to 6, WA600 was used and the content of the transparent particles 16a in the transparent resin layer 16 was varied. The content was calculated by sandwiching the transparent resin layer 16 containing the transparent particles 16a between two glass plates and using a microscope to count the number of the transparent particles 16a in a field of view under a magnification of 500 times. In Example 4, the content of the transparent particles 16a was set to 4 vol %. Further, the thickness of the transparent resin layer 16 was set to have an average of 12.2 μm and a standard deviation of 2.9. In Example 5, the content of the transparent particles 16a was set to 16 vol %. Further, the thickness of the transparent resin layer 16 was set to have an average of 14.1 μm and a standard deviation of 4.5. In Example 6, the content of the transparent particles 16a was set to 24 vol %. Further, the thickness of the transparent resin layer 16 was set to have an average of 14.2 μm and a standard deviation of 3.8.

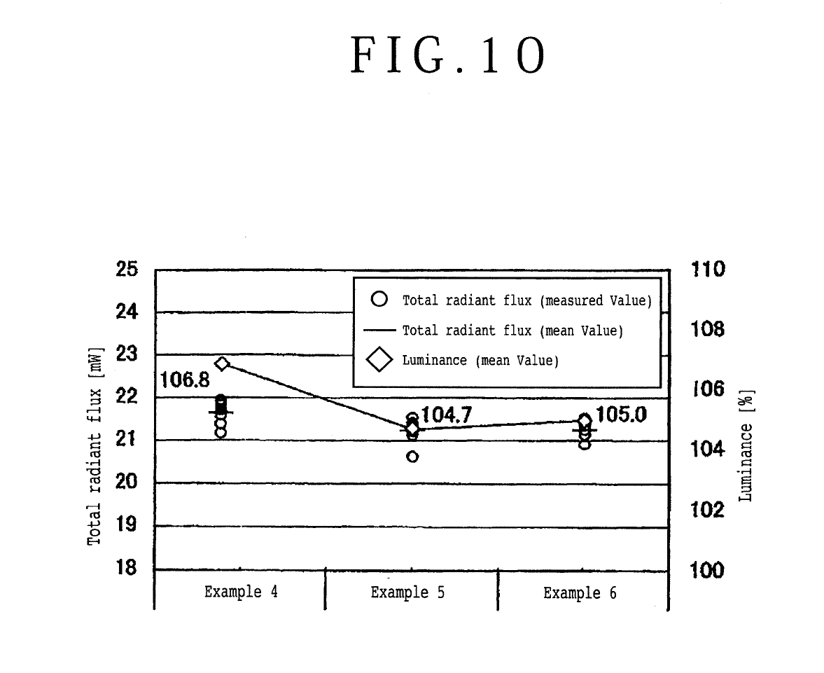

As shown in FIG. 10, the luminance in Examples 4 to 6 is improved over that (100%) in Comparison by 4.7 to 6.8%, so that the light extraction efficiency can be improved. Further, it was confirmed from the above-mentioned conditions of Examples 4 to 6 and the results shown in FIG. 10 that the lower the content of the transparent particles 16a, the higher the luminance of the light emitting diode. As a reason for this tendency, it is supposed that the lower the content of the transparent particles 16a, the greater the proportion of light emitted from the side surface of the transparent resin layer 16.

As the transparent particles 16a in Examples 7 to 12, glass particles such as glass frit or glass bead were used. In Examples 7 and 8, glass frit (CF0003-20C manufactured by Nippon Frit Co., Ltd.) was used as the transparent particles 16a. This glass frit was set to have a refractive index of 1.58 and a median particle size of 25 μm. In Examples 9 and 10, glass frit (CF0027-20C manufactured by Nippon Frit Co., Ltd.) was used as the transparent particles 16a. This glass frit was set to have a refractive index of 1.48 and a median particle size of 21 μm. In Examples 11 and 12, glass bead (CF0055WB15-01 manufactured by Nippon Frit Co., Ltd.) was used as the transparent particles 16a. This glass bead was set to have a median particle size of 20 to 30 μm. The content of the transparent particles 16a in Example 8 was set higher than that in Example 7. The content of the transparent particles 16a in Example 10 was set higher than that in Example 9. The content of the transparent particles 16a in Example 12 was set higher than that in Example 11.

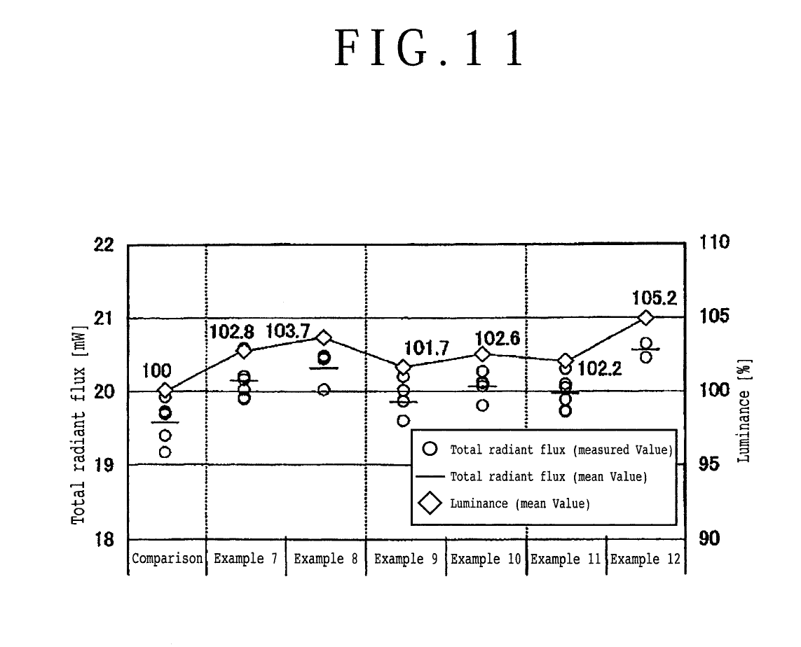

As shown in FIG. 11, the luminance in Examples 7 to 12 is improved over that (100%) in Comparison by 2.2 to 5.2%, so that the light extraction efficiency can be improved. Further, it was confirmed from the above-mentioned conditions of Examples 7 to 12 and the results shown in FIG. 11 that the higher the content of the transparent particles 16a, the higher the luminance of the light emitting diode. As a reason for this tendency, it is supposed that the glass particles have good transparency.

The present invention is not limited to the above preferred embodiments, but various modifications may be made. The size, shape, etc. of the parts in the above preferred embodiments shown in the attached drawings are merely illustrative and they may be suitably changed within the scope where the effect of the present invention can be exhibited. Further, the above preferred embodiments may be suitably modified without departing from the scope of the object of the present invention.

For example, while the device chip 14 is formed by using a sapphire substrate and GaN based semiconductor materials in the above preferred embodiments, the crystal growing substrate and the semiconductor materials are not limited. For example, a GaN substrate may be used in place of the sapphire substrate as the crystal growing substrate. Further, while the crystal growing substrate such as a sapphire substrate is preferably made thin for the purpose of easy processing, a reduced thickness of the crystal growing substrate is not necessarily required.

Further, while the stacked layer 142 is composed of an n-type semiconductor layer, a semiconductor layer as a light emitting layer, and a p-type semiconductor layer stacked in this order in the above preferred embodiments, the configuration of the stacked layer 142 is not limited to this configuration, but may be changed to any configuration capable of emitting light by using the recombination of electrons and holes.

Further, the device chip 14 may be changed to a device chip (AlGaAs, GaAsP, etc.) capable of emitting infrared light. In this case, an effect similar to that of the above preferred embodiments can be obtained by using a material capable of transmitting infrared light as the material of the transparent member 15. Further, also in the case that the device chip 14 emits ultraviolet light and the transparent member 15 is formed of a material capable of transmitting ultraviolet light, an effect similar to that of the above preferred embodiments can be obtained.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A light emitting chip comprising:
a device chip having a transparent substrate and a light emitting layer formed on a front side of said transparent substrate;
a transparent resin layer provided on a back side of said transparent substrate; and
transparent particles contained in said transparent resin layer for transmitting and scattering light emitted from said light emitting layer.

2. The light emitting chip according to claim 1, wherein said transparent substrate includes a sapphire substrate, and said light emitting layer includes a GaN semiconductor layer.
